(19) United States
(12) Patent Application Publication
(10) Pub. No.: US 2023/0147184 A1
(43) Pub. Date: May 11, 2023

(54) Air transport unit

(71) Applicant: LED iBond International A/S, Hørsholm (DK)

(72) Inventor: Lars FREDERIKSEN, Gentofte (DK)

(73) Assignee: LED iBond International A/S, Hørsholm (DK)

(21) Appl. No.: 17/802,707

(22) PCT Filed: Feb. 26, 2021
(86) PCT No.: PCT/DK2021/050056

§ 371 Date: Aug. 26, 2022

(30) Foreign Application Priority Data
Feb. 26, 2020 (DK) PA 2020 70125

(51) Int. Cl. A01G 9/24; H05K 1/02; A01G 7/04; A01G 9/02

(52) U.S. Cl. CPC A01G 9/246; H05K 1/0272; A01G 7/045; A01G 9/247; A01G 9/023; H05K 2201/09063; H05K 2201/0929; H05K 2201/10106

(57) ABSTRACT

An air transport unit comprising a composite board. The composite board comprising an anode layer and a cathode layer of an electrically conducting material. The anode layer and cathode layer are separated by an insulator of an electrically insulating material. The composite board further comprising an electric component in electrical connection with the anode layer and the cathode layer. The air transport unit further comprising a carrier board, wherein the composite board and the carrier board each have a duct forming surface, which carrier board and composite board are arranged so that an air duct forms between the duct forming surfaces.

### CROSS REFERENCE TO RELATED APPLICATIONS

The instant application is a U.S. National Stage application of and claims priority to PCT/DK2021/050056, filed on Feb. 26, 2021, which is a PCT application of and claims priority to DK Application No. PA 2020 70125 filed on Feb. 26, 2020, the subject matter of both aforementioned applications are hereby incorporated by reference in their entireties.

### FIELD OF THE INVENTION

The present invention relates to an air transport unit. The air transport unit comprises a composite board with two layers of an electrically conducting material separated by an insulator and an electric component, and a carrier board. The air transport unit has an air duct, so that the air transport unit is useful for transporting air, and the invention also relates to a vertical farming system comprising the air transport unit.

### BACKGROUND

Composite boards are well known construction elements for light emitting diode (LED) based lamps where two electrically conducting plates separated by an insulating material are used to supply electricity to and from LEDs mounted in the composite board. For example, WO 2015/104024 discloses a construction element where an electronic component is connected to a composite board using an appropriate adapter. WO 2015/104024 also discloses transmission of data to an electronic component in the construction element using power line communication using the electrically conducting plates.

WO 2017/121430 and WO 2018/077359 disclose electrical supply systems where composite boards serve as electrical supply and extension modules for providing electricity, and data communication, to electronic components in the respective modules.

The systems of WO 2017/121430 and WO 2018/077359 and the construction element of WO 2015/104024 are useful in so-called “Internet of Things (“IoT”) applications and provide flexibility for building IoT devices, but they do not generally provide functions beyond supplying electricity and data to electronic components in the respective composite boards. WO 2019/243618, in contrast, discloses a board where the electronic components are UV LEDs, which may be used for sterilisation. The device of WO 2019/243618 may have an axial hollow interior being part of a flushing arrangement allowing that the device can flush and sterilise a teat cup.

The present inventor believes that composite boards may have further advantageous applications, and it is an object of the invention to provide a unit having further applications than suggested in the prior art.

### SUMMARY OF THE INVENTION

A first aspect of the present invention relates to an air transport unit comprising a composite board comprising an anode layer and a cathode layer of an electrically conducting material, which anode layer and cathode layer are separated by an insulator of an electrically insulating material, the composite board further comprising an electric component in electrical connection with the anode layer and the cathode layer, the air transport unit further comprising a carrier board, wherein the composite board and the carrier board each have a duct forming surface, which carrier board and composite board are arranged so that an air duct forms between the duct forming surfaces.

In general, each of the composite board and the carrier board of the air transport unit have a surface facing the air duct, i.e. the duct forming surface, and an opposite surface. The opposite surface faces away from the air duct, and the opposite surface may also be referred to as the “ambient surface”. The opposite surface can also be considered to face the ambient environment, and in the context of the invention, the term “ambient environment” refers to the environment adjacent to the opposite surfaces, e.g. the ambient surfaces. For example, when multiple air transport units are included in a vertical farming system, the ambient environment may be the space between the air transport units. However, the air transport unit is not limited to vertical farming systems, and when the air transport unit is used in an indoor ventilation arrangement, i.e. especially when the air transport unit has a ventilation hole, in particular a ventilation hole with a ventilation unit, the ambient environment may be a space where ventilation is appropriate, e.g. in a kitchen above a stove or the like, inside a living room where ventilation is desirable, inside a fume hood, e.g. inside a laminar air flow bench, etc. The duct forming surfaces face each other so that the air duct forms between the duct forming surfaces. In the context of the invention a “duct forming surface” is a surface forming or at least partly forming an air duct.

In the context of the invention an air duct may be a passage, wherein the movement of air can take place. In general, the air duct will have an air inlet and an air outlet. Moreover, the air inlet and the air outlet may define a flow direction in the air duct so that the air outlet is downstream of the air inlet, and any electronic component in the air transport unit may be defined in terms of its position relative to the air inlet or the air outlet, e.g. an electronic component may be defined as downstream from the air inlet or upstream from the air outlet. The air inlet and the air outlet may be placed anywhere along the air duct. The air transport unit may also comprise a plurality of air inlets and/or a plurality of air outlets.

It is also contemplated that the flow direction is reversible so that an air inlet may also be an air outlet, and vice versa an air inlet may also be an air outlet. In certain embodiments, the air inlet and/or the air outlet may comprise one or more valves, e.g. one-way valves, to control a flow rate and direction of flow through the air inlet and/or the air outlet.

The air duct is for transporting air, although it is also contemplated that the air duct may be for transporting other fluids than air, such as water, fertiliser, or insect spray, etc.

In a specific embodiment, the air transport unit has an air inlet at inlet end and an air outlet at an opposite outlet end, e.g. the air transport unit has an elongate shape with a longitudinal axis from the air inlet to the air outlet. The air transport unit may also have one or more ventilation holes in the composite board. The inlet end of the air transport unit may comprise a coupling device and the outlet end may comprise a complementary coupling device, where the coupling device and the complementary coupling device may be coupled, e.g. releasably coupled, to form a common air duct between a first and a second air transport unit. This embodiment is especially useful when the air transport unit is used in a ventilation arrangement for indoor use, although this embodiment may also be used in the vertical farming system of the invention. Furthermore, the air transport unit with the coupling device and the complementary coupling device may also comprise a longitudinally arranged pipe for a sprinkler system, which pipe, e.g. at the inlet end and the outlet end of the air transport unit, may comprise a coupling device and the complementary coupling device, respectively, allowing the pipe of a first air transport unit to be fluidly connected to the pipe of a further air transport unit. Thereby, the air transport unit may be used in a vertical farming system having a simplified liquid, e.g. water, supply.

The air transport unit has an opposite surface, i.e. the composite board and the carrier board each have an opposite surface, facing away from the air duct, and these opposite surfaces may be considered to define the orientation of the air transport unit. For example, the opposite surface of the carrier board surface may be an upper surface of the air transport unit, and the opposite surface of the composite board may be a lower surface of the air transport unit, or vice versa. Surfaces of the composite board and the carrier board of the air transport unit may be functionalised as desired, regardless of their orientation. For example, the composite board has an electric component in electrical connection with the anode layer and the cathode layer, and this electronic component may be mounted in a recess in the composite board, e.g. a recess through the anode layer, the electrically insulating layer and the cathode layer, a recess through the anode layer and the electrically insulating layer, or a recess through the cathode layer and the electrically insulating layer, so that the electronic component, e.g. an LED, faces away from the air duct, e.g. the electronic component faces the ambient environment, or the electronic component faces the air duct.

In a preferred embodiment, the carrier board provides an upper surface of the air transport unit, e.g. the surface facing away from the air duct, and the surface is configured to house a growing organism. For example, the surface may be designed to hold a growth medium for an organism. The growing organism may be any organism as desired, e.g. a plant, a fungus, an insect etc., and the growth medium will be selected accordingly. In the embodiment where the carrier board provides the upper surface, and the upper surface is configured to house a growing organism, the composite board, e.g. as the board comprising the lower surface of the air transport unit, may comprise one or more LEDs as the electric components, which LEDs may be configured to emit light at a wavelength within the photosynthetically active radiation (PAR) and/or ultraviolet light and/or infrared light. The LEDs are preferably mounted in the lower surface facing away from the air duct. Air transport units according to this preferred embodiment may be “stacked”, so that one air transport unit provides an upper surface for a growing organism, which can be placed below a further air transport unit having LEDs mounted in a lower surface facing towards the upper face of the one transport unit, the LEDs may be of an appropriate wavelength to support growth of the organism on the air transport unit below the LEDs, and the further air transport unit may also provide an upper surface configured to house a growing organism, which may synergise with yet another air transport unit. Thereby, the air transport units allow for a compact vertical farming system to be designed, furthermore such a system is easy to upscale for industrial use since the number of air transport units such a system may comprise is virtually unlimited.

In a specific embodiment, the air transport unit, especially the surface of the carrier board defining an upper surface for housing a growing organism, comprises a wall extending from the surface of the carrier board. Alternatively, the wall may extend from a surface of the composite board, e.g. when the surface of the composite board is the upper surface of the air transport system. The wall may thus extend from any surface of the carrier board or the composite board. The wall may appropriately ensure that a growth medium is retained on the surface where the wall is located.

The wall may extend substantially perpendicular from a surface of the carrier board or composite board. The wall may extend at an acute or obtuse angle from a surface of the carrier board or composite board. The wall preferably extends from a surface of the carrier board either opposite or connecting to the duct forming surface of the carrier board.

The wall may form an enclosure on the surface. For example, such enclosure may be in the form of one, two, three, four or more side walls extending from a surface of the carrier board, in particular the upper surface for housing the growing organism. The enclosure with one or more sidewalls may be used for containing growth medium, e.g. organic matter such as soil, which is especially advantageous if the air transport unit is to be used for farming of crops, such as flowers, vegetables, or fruits. The enclosure may be suitable for use as an aquarium, e.g. for hobby use or for industrial use, e.g. aquafarming. The enclosure may be suitable for use as a terrarium for farming of insects. In some cases, the enclosure may contain a top for closing off the enclosure, which might be especially useful if the enclosure is used for farming of insects. The wall(s) extending from the carrier board may define one, two, three or more separate enclosures on the carrier board.

The wall may be an integral part of the carrier board or composite board or the wall may be a separate part, which is stationary or movably fastened to the carrier board or composite board. In an embodiment where the carrier board and/or the composite board are formed by extrusion the wall may be formed during the extrusion of the composite board or the carrier board. Thereby, extrusion of the boards allows for simplified manufacture of an air transport unit according to the invention appropriate for a vertical farming system.

The wall may be hingedly connected to the carrier board, e.g. if the carrier board is for a growth organism, such as crops or insects, the carrier board may comprise one, two, three, four or more walls defining an enclosure for the growing organism, and in such cases it may be advantageous if the wall(s), or at least a part of the wall(s) are hingedly connected to allow easy access to the growing organism.

The wall may comprise and/or consist of wood, polymer, plastics, steel, plastic, alloy, glass, metal, etc. The wall may be formed from a plurality layers, wherein the plurality of layers may differ in both thicknesses and/or material.

The walls extending from the carrier board or composite board may in some embodiments comprise an anode layer and a cathode layer of an electrically conducting material. Where the anode layer and the cathode layer are separated by an insulator of an electrically insulating material. The wall may comprise an electric component in electrical connection with the anode layer and the cathode layer. The wall may be modified to substantially match the composite board. The wall may be modified to substantially match the layers and/or the components of the composite board. The wall may differ or match the composite board in length, thickness and/or width.

A wall may also extend from the composite board or the carrier board and into the air duct, e.g. to form paths within the air duct.

The air duct generally has an air inlet and an air outlet. The air inlet and the air outlet may be located anywhere along the air duct, and the air inlet and the air outlet may face any surface as desired. In an embodiment the composite board comprises a ventilation hole extending through the anode layer, the insulator and the cathode layer, which ventilation hole is configured to facilitate an air flow between the air duct and ambient environment of the air transport unit. The ventilation hole may thus be considered to be either or both of an air inlet and an air outlet. The ventilation hole may be appropriately located in the composite board when the composite board provides the lower surface of the air transport unit, and when the air transport unit has an upper surface, especially when the carrier board provides the upper surface, configured to house a growing organism. Thereby, the air transport unit may be used in a vertical farming system, so that the air duct of a first air transport unit can exchange the air for a growing organism located on a surface, e.g. an upper surface of a further air transport unit, below the first air transport unit. This allows that a compact vertical farming system is provided. In a preferred embodiment the air inlet and/or the air outlet are formed by connecting the composite board and carrier board to create one or more opening in-between the composite board and the carrier board, e.g. by having elements placed in-between the carrier board and the composite board distancing them away from each other, and/or by curving composite board and/or the carrier board to form an opening in-between these.

When the composite board has a ventilation hole the air transport unit may advantageously have an air inlet at a location where it does not face a growing organism. Thereby, the air for the growing organism can be exchanged and controlled as appropriate, e.g. with respect to the content of CO₂ and other components.

The composite board may comprise any number, e.g. one, two, three or more, of ventilation holes. The ventilation hole may be formed as part of an anti-draught air vent. The ventilation holes may assume any cross-sectional shape, e.g. round, rectangular, or triangular. The ventilation hole may help in facilitating heat control of an electric component in electrical connection with the composite board by providing natural ventilation. In an embodiment where the air transport unit has a substantially planar geometric configuration, ventilation holes may be formed at longitudinal ends of the composite board, thereby facilitating a longitudinal airflow through the air duct. Ventilation holes may also be formed in areas of the composite board with higher heat generation, to further facilitate cooling of such areas, e.g. areas with a higher density of electric components.

In an embodiment the ventilation hole comprises a ventilation unit in electrical connection with the anode layer and the cathode layer. The ventilation unit may be any unit capable of facilitating a flow of a fluid through the ventilation hole in any direction. The ventilation unit may be an electrically driven ventilator, e.g. a fan ventilator. The ventilation unit may be a supply fan for supplying air from an ambient environment to the air duct. The ventilation unit may be an exhaust fan for drawing air out from the air duct. The composite board may comprise a plurality of ventilation units, wherein the ventilation units within the plurality of ventilation unit may differ from each other. In some embodiment the air duct may be provided with fittings for mounting ventilation units within the air duct, for further facilitating an air flow through the air duct. The ventilation unit may be configured to provide an exhaust/supply air flow of 30-100 L/min. The ventilation unit may be provided with filters for filtering an air flow through the ventilation unit. A ventilation unit is especially preferred in combination with a CO₂ sensor as an electric component so that the CO₂ may be monitored and the ventilation controlled accordingly.

The air duct may comprise path forming surfaces for defining one, two, three or more paths within the air duct. The path forming surfaces may be adapted to form a meandering path for air being transported in the air duct, e.g. a zig-zag path, a spiraling path, etc. In some embodiments the path forming surfaces forms one, two, three or more paths for air, and/or one, two, three or more paths for fluid(s) other than air. For example, the composite board may comprise one or more first electric components and one or more second electric components, the path forming surfaces may then form one or more paths for transporting air over the one or more first effect electric components, and the path forming surfaces may form one or more additional paths for transporting air over the one or more second electric components. In an embodiment where the one or more second electric components has a higher heat output than the one or more first electric components, it may be preferable if the paths over the one or more second electric components has a higher flow rate than the paths over the first electric components, and/or water is transported over the one or more second electric components. The air transport unit may be formed with air paths for different electrical groups, e.g. a path for LEDs and a path for sensors. The path forming surface may also be provided to form one or more housing sections, e.g. sections where an airflow is not facilitated. The one or more housing sections may be used for housing electric components, spare parts, fluids, etc. The path forming surfaces may be used for structural purposes to support and/or to connect the composite board and/or the carrier board. The one or more housing sections may be formed within the air duct, and/or outside of the air duct.

The air transport unit according to the first aspect of the invention allows for convenient and controlled heat control of an electric component in electrical connection with a composite board of the air transport unit. For example, the electrically conducting anode and cathode layers may be customised both in shape and in the electric component(s) in connection with the electrically conducting layers, thereby providing a flexible and highly configurable solution which may be used for a wide variety of purposes.

The composite board may have any shape as desired if it comprises the at least two layers, i.e. the anode layer and the cathode layer, of electrically conducting material separated by the electrically insulating material. The anode layer and cathode layer are separated by an insulator of electrically insulating material. In the context of the invention the term “separate” and its derived forms mean that direct electrical contact between the anode layer and the cathode layer is prevented in order to prevent short circuits between the anode layer and the cathode layer. The composite board may comprise additional elements as desired in order to separate the anode layer and the cathode layer, or the insulator of the electrically insulating material may be the only element separating the anode layer and the cathode layer.

The dimensions of the composite board and the carrier board may be selected freely. For example, the air transport unit, and thus the composite board and the carrier board, may have a width in the range of 10 cm to 125 cm, e.g. 25 cm to 100 cm, and a length in the range of 10 cm to 500 cm. In general, the composite board has a thickness reflecting the thickness of the insulator, e.g. in the form of an electrically insulating layer, plus the two electrically conducting layers. The thickness of the composite board is typically in the range of 2 mm to 50 mm. The other two dimensions will typically reflect the intended use of the composite board, e.g. as a lighting fixture, and in a certain embodiment the composite board has a size according to recognised standards. For example, the air transport unit may be sized to fit under e.g. a kitchen cabinet or the like. Thus, the composite board may have a width of about 600 mm.

The anode layer of the composite board is electrically connected to an anode of the electronic component, and the cathode layer of the composite board is electrically connected to a cathode of the electronic component, but the anode layer and the cathode layer are otherwise not limited. The anode layer may also be referred to as a “first layer” and the cathode layer may also be referred to as a “second layer”. Either of the anode layer or the cathode layer may represent a front layer or a back layer of the composite board. In the context of the invention the anode layer and the cathode layer may be referred to collectively as the “electrically conducting layers” or “conducting layers”.

The composite board may be extending in two dimensions so that it can be described as “planar”. A planar composite board is not limited with respect to thickness, and in general the thickness is defined by the combined thicknesses of the anode layer, the cathode layer and the insulator. The composite board may also be defined in three dimensions and e.g. have a shape representing a section of a sphere, e.g. a hemispherical shape, or an arch. Non-planar composite boards will also have a thickness as defined by the combined thicknesses of the anode layer, the cathode layer and the insulator, and a non-planar composite board is also not limited with respect to its thickness.

The electrically conducting material may be chosen freely, and the conducting layers may be from any conducting material. Likewise, the conducting material may have any thickness as desired. However, it is preferred that the electrically conducting material comprises or is a metal. Preferred metals are metals selected from the list consisting of aluminium, magnesium, copper, titanium, steel, and their alloys. Metals may be anodised to provide the metal with an oxide layer on the surface, and in an embodiment the metal is anodised, e.g. by providing an oxide layer having a thickness of at least 10 μm. When the metal is anodised, the outer surface of the metal is electrically insulating so that an end user is protected from currents running through the electrically conducting materials, i.e. the anode layer and the cathode layer. Anodisation further protects the metal from being corroded. In particular, an electric current running through the anode layer or the cathode layer can make the metal more prone to corrosion but by anodising the metal such corrosion is prevented. Anodisation is especially relevant when the anode layer and/or the cathode layer is constructed from aluminium, magnesium or titanium, or alloys based on these metals. For example, these layers may be anodised to provide oxide layers of at least 10 μm thickness, e.g. about 20 μm Al₂O₃. Anodised aluminium, magnesium, or titanium has a protective insulating layer, which may prevent short circuiting and electrical shocks.

In some embodiments the electrically conducting layers may be used to provide data communication with the electronic component using power line communication (PLC), e.g. direct current PLC. When data communication is desired the composite board may be fitted with appropriate data ports, e.g. standardised ports, such as those known as USB, HDMI, Display Port, etc. When data ports are included, appropriate electronic components will typically also be integrated in the composite board. Furthermore, it is preferred that the composite board comprises two or more electric components in electrical connection with the anode and the cathode layers, as appropriate, and that each of the two or more electric components has a controller. Thereby, each of the two or more electric components can receive and/or send a different data signal via the electrically conducting layers, e.g. via PLC.

In an embodiment the anode layer and/or the cathode layer has been extruded from a metal, e.g. from aluminium, magnesium, copper, titanium, or steel. In a preferred embodiment the anode layer and/or the cathode layer are formed with trenches in the extrusion process. For example, the trenches may be present along a longitudinal axis of the respective layer through the length of the layer. The trenches may be used for electrically separating electric components in the composite board. Extrusion of the anode layer and/or the cathode layer is advantageous since it allows manufacture of the respective layer with the trenches formed in the extrusion process so that a cheaper process is provided compared to providing a sheet metal or similar and creating the trenches in the layers. Likewise, extrusion allows preparation of an anode layer and/or a cathode layer having a non-uniform thickness. Alternatively, trenches may be formed in the anode and/or cathode layer by milling. Milling may be especially advantageous if the trenches should bend or turn.

The insulator may have any form desired and the electrically insulating material may be any electrically insulating material. It is preferred that the insulating material comprises a flame retardant. In some embodiments the insulator layer may also partly or fully consists of an air layer separating the electrically conducting layers. In an embodiment the insulator has the form of a sheet between the anode layer and the cathode layer, which may also be in the form of sheets, or which may be extruded to have another form. When the insulator has the form of a sheet its area generally corresponds to at least 50% of the area of the anode layer and/or the cathode layer. The insulator may also define a honeycomb structure or another discontinuous structure. For example, the insulator may take the form of a plurality of pillars or the like between the anode layer and the cathode layer. A plurality of pillars is especially preferred when the electrically conducting layers have been extruded. In an embodiment the insulator may be formed by insulating oxides created on the anode and/or the cathode layer, e.g. by anodizing the anode layer and/or the cathode layer.

The electrically insulating material is preferably a polymeric material. The electrically insulating material may be of low density. For example, the electrically insulating material may comprise an expanded or foamed material (open and/or closed celled), such as expanded polystyrene, and/or a reinforced material such as a fibre glass material. The electrically insulating layer may be made of a polymer material such as amorphous plastic materials (e.g. polyvinylchloride, polycarbonate and polystyrene) or crystalline plastic materials (e.g. Nylon, polyethylene and polypropylene), or wood.

It is significant that the insulator separates the anode layer from the cathode layer in order to prevent short circuits, and it is possible that the insulator comprises an electrically conducting material as long as the anode layer is separated from the cathode layer. For example, the insulator may comprise a core of a different material, even a metal, providing strength and rigidity.

In an embodiment the anode layer and the cathode layer, which may be extruded metals, are glued together with an electrically non-conducting glue so that the glue is the insulator. This allows a thinner layer of the insulator, e.g. in the range of 0.2 mm to 0.5 mm. In an embodiment wherein, the anode layer and/or the cathode layer comprises an insulating surface oxide, the anode layer and the cathode layer may be bonded together by annealing.

The composite board may comprise one or more adapters capable of being mounted in a hole or recess in the composite board and thereby establishing electrical connection between the conducting layers. The one or more adapters being configured for receiving one or more electric components in an electrical connection. The hole may extend entirely through or partly through the composite board. The adapter may comprise a retaining element corresponding to a section of the perimeter of the hole or the whole perimeter of the hole. A retaining element is especially suited when the hole is provided in a pre-assembled composite board, e.g. in the form of a dibond plate. However, the hole may also be established in each of the layers, e.g. in the anode layer and the insulator before assembly of the layers. When the hole has been established prior to assembly of the layers, the retaining element is generally not needed. In particular, the holes in the anode layer (or the cathode layer, as desired) and the hole in the insulator may be sized so that the hole in the insulator is larger than the hole in the anode or cathode layer thereby providing a retaining function. For example, the retaining element may be designed so that the adapter can be press fitted into the hole, or the hole and the retaining element may comprise complementary engagement means. Complementary engagement means may be an external thread on the retaining element and a corresponding internal thread in the hole. In an embodiment, a hole, e.g. round, square, or rectangular, is provided in the anode layer or the cathode layer as desired, and the electrically conducting layers are aligned with an insulator having a larger hole than provided in the respective conducting layer.

The adapter may also be soldered or glued to the composite board. The retaining element may be made of a polymer or a metal or a combination of a polymer and a metal. The adapter may comprise any other component or element as appropriate. In a certain embodiment the adapter may be removably fitted in the hole. In another embodiment the adapter is permanently fitted in the hole meaning that its removal will destroy the adapter and/or the composite board.

The hole preferably has a round perimeter, but it may also have a square or rectangular perimeter, or a perimeter of another shape. The hole may have any appropriate size, but in a certain embodiment the hole has a first dimension in the range of 5 mm to 50 mm, and a second dimension in the range of 5 mm to 50 mm. For example, the hole may be round and have a diameter in the range of 5 mm to 50 mm. The hole may also be larger, e.g. having a diameter up to or at 100 mm.

In an embodiment, the adapter comprises a circuit board, e.g. a printed circuit board (PCB), and any element necessary to establish the electrical connections. For example, the hole in the composite board may go through the front layer, whether this is the anode layer or the cathode layer, and the insulator but not the back layer so that the back layer forms a support for the circuit board, which is glued to the back layer. It is preferred that the glue, e.g. in a layer of a thickness in the range of 50 μm to 100 μm, is both electrically and thermally conducting so that the gluing establishes the electrical connection from the electronic component to the back layer and further leads excess heat away from the electronic component. This is especially advantageous when the electronic component is a LED and the back layer is aluminium. Electrical connection from the front layer to the circuit board may be established using an electrically conducting element, e.g. a resilient element in press between the front layer and the circuit board. The circuit board may be any component capable of carrying the electronic component and establishing electrical connection from the first layer to an anode of the electronic component and electrical connection from the second layer to a cathode of the electronic component. The circuit board is not limited to a “board” shape and is defined solely functions outlined above. In its simplest form the “circuit” of the circuit board provides electrical contacts between the anode and the cathode of the electronic component and the two conducting layers, respectively. The circuit board may be any kind of material, e.g. plastic, metal etc., provided with the circuit for transmission of electricity. The circuit may be attached to the circuit board in any way, e.g. by printing, soldering, gluing or the like. In a certain embodiment the circuit board is a PCB.

Composite boards and adapters as described above are known from WO 2017/121430 and WO 2015/104024 which are incorporated by reference in their entireties herein.

The carrier board may have any shape as desired. The size of the carrier board may be selected freely. In some embodiments the carrier board may have a size and shape substantially corresponding to that of the composite board. The thickness of the carrier board may reflect the purpose of the carrier board, and the requirements towards mechanical strength. The thickness of the carrier board is typically in the range of 2 mm to 50 mm. The other two dimensions will typically reflect the intended use of the carrier board, e.g. as a carrier of material, or for adding structural integrity to the air transport unit.

The carrier board may be extending in two dimensions so that it can be described as “planar”. The carrier board may also be defined in three dimensions and e.g. have a shape representing a section of a sphere, e.g. a hemispherical shape, or an arch, e.g. as also described above for the composite board.

The carrier board may be manufactured from a wide variety material. The carrier board may comprise or consist of wood, polymer, plastics, steel, plastic, alloy, glass, metal, etc., e.g. if the carrier board is unexpected to be exposed to high loads it may be preferable to have the carrier board manufactured from high strength steel, or if the carrier board is designed to act as a support for organic matter, it may be preferable to have the carrier board manufactured from a non-toxic and/or a non-contaminating material, such as a ceramic, biopolymer, or a surface passivated material. The carrier board may be formed from extrusion.

The carrier board may in some embodiments comprise an anode layer and/or a cathode layer of an electrically conducting material. When the carrier board comprises an anode layer, this anode layer may be in electrical connection with the anode layer of the composite board, and likewise, when the carrier board comprises a cathode layer, this cathode layer may be in electrical connection with the cathode layer of the composite board. When the carrier board comprises both an anode layer and a cathode layer, these may be in electrical connection with the anode layer and the cathode layer of the composite board, respectively. Furthermore, the when the carrier board comprises both an anode layer and a cathode layer, these may be separated by an insulator of an electrically insulating material, e.g. the carrier board may also be a “composite board” as defined for the invention, and any feature relevant for the composite board is equally relevant for the carrier board when this comprises both an anode layer and a cathode layer separated by an insulator of an electrically insulating material. The carrier board may also comprise an electric component in electrical connection with the anode layer and the cathode layer. The carrier board may be modified to substantially match the composite board in size. The carrier board may be modified to substantially match the layers and/or the components of the composite board, while differing or matching the composite board in length, thickness and/or width.

The carrier board may be formed from a plurality layers, wherein the plurality of layers may differ in both thicknesses and/or material. For example, in the case where the carrier board is expected to be exposed to high loads while carrying an organic material, it may be preferable to have the organic material resting on a thin layer, e.g. 1 mm to 10 mm, of a non-toxic and/or a non-contaminating material, while having a thick layer, e.g. 10 mm to 50 mm, of high strength material for adding structural integrity to the carrier board. If the air transport unit is to be used as a construction component it may be preferable to have the carrier board manufactured from stainless steel.

A group of electric components in the context of the invention may be interpreted as one or more of the same electric components, e.g. a group of electric components being formed by three blue LEDs. A group of electric components may be interpreted as a grouping of different electric components, e.g. a ventilation unit and an LED may form an electrical group.

In an embodiment the electric component is one or more LEDs, the anodes of which are in electrical connection with the anode layer and the cathodes of which are in electrical connection with the cathode layer, wherein the one or more LEDs are configured to emit light at a wavelength within the photosynthetically active radiation (PAR) and/or ultraviolet light and/or infrared light away from the surface of the composite board opposite the air duct.

The composite board may be provided with several different LEDs emitting light at different wavelengths and/or intensities, and the one or more LEDs may be controlled individually, e.g. using power line communication (PLC). The one or more LEDs in electrical connection with the composite board may be used for emulating a day cycle. If the air transport unit is to be used in a farming system, it may be advantageous to provide one or more LEDs emitting light at a wavelength within PAR, e.g. in the interval of 400-700 nm. The composite board may be provided with one or more infrared LEDs for facilitating heating. The composite board may be provided with one or more ultraviolet LEDs, e.g. if the air transport unit is installed in a kitchen or a hospital the usage of ultraviolet LEDs for sterilisation may be advantageous.

The one or more LEDs may be provided to emit light into the air duct, e.g. using ultraviolet LEDs for sterilising an air flow through the air duct. Likewise, infrared LEDs can be used for heating the air in the air duct.

The one or more LEDs may be connected on a surface of the composite board opposite the duct forming surface, thereby being able to emit light from and away from the surface of the composite board opposite the duct forming surface.

In an embodiment, where the air transport unit is used for vertical farming, the one or more LEDs are placed throughout the composite board to achieve uniform illumination of a carrier board of another air transport unit placed substantially directly vertically below the air transport unit. However, illumination may also be non-uniform, e.g. with respect to colour and/or light intensity.

In an embodiment the electric component is a liquid pump and the air transport unit further comprise a sprinkler system comprising a pipe in fluid communication with a liquid reservoir and the liquid pump, the pipe having a sprinkler configured to distribute a liquid from the surface of the composite board opposite the air duct. The sprinkler system may be a sprinkler system configured for irrigating plants and/or for providing water to animals. The sprinkler system may be used for aromatic purposes, e.g. if the air transport unit is used as lighting unit in a building it may be desirable to use the sprinkler system for spreading a scent and/or an air freshener for removing unwanted odours. The sprinkler system may also comprise a reservoir for a fertiliser and/or for a pesticide.

The sprinkler may be a standard sprinkler known within the field of irrigation. The sprinkler may be configured for atomising a liquid exiting the sprinkler, thereby turning it into an aerosol. The sprinkler may be fitted in a recess/through-going hole of the composite board on a surface opposite the duct forming surface of the composite board. The sprinkler being in fluid communication with the pipe. The air transport unit may also comprise a plurality of sprinklers in fluid communication with one or more pipes.

The pipe may extend within the air duct and/or be connected to either the carrier board and/or the composite board. The pipe may be part of a piping system configured for transporting liquid from the liquid pump to the sprinkler. The air transport unit may comprise the liquid reservoir, e.g. the liquid reservoir being situated within the air duct and/or is connected to either the carrier board and/or the composite board. The liquid reservoir may be an external reservoir connectable to the pipe of the sprinkler system.

The liquid pump may be situated within the air duct and/or be connected to either the carrier board and/or the composite board. The liquid pump being configured to pump a liquid from the liquid reservoir and through the pipe to the sprinklers, which may then sprinkle the liquid pumped by the pump.

In an embodiment the electric component is selected from the list consisting of a heating unit, a cooling unit, a sensor, a controller, a microphone, a camera, a radio transmitter, a radio receiver, an antenna and an access point for wireless communication.

A heating unit may be provided to heat an air stream passing through the air duct. The heating unit may be used for allowing the air transport unit to be used in cold outdoor/indoor environment, e.g. farming during winter time, where a heating unit may be used for keeping frost away. The heating unit may also be configured to directly heat the composite board and/or the carrier board. The heating unit may be resistance heating coils, a fan heater, a heat pump, etc.

A cooling unit may be provided to cool an air stream passing through the air duct. The cooling unit may be used directly for cooling another electric component. The cooling unit may be used for cooling the carrier board to avoid overheating of a material carried by the carrier board and/or the composite board. The cooling unit may be an evaporative cooler, vapour-compression refrigerator, absorption refrigerator, air conditioning unit, etc.

A sensor may be provided to monitor any parameter, e.g. soil pH, air moisture, soil moisture, soil temperature, air temperature, air flow, O₂ level, CO₂ level, light intensity, voltage, and/or ampere. The sensor may be configured to transmit sensor data either wirelessly or through a wired connection to a processor unit. The processor unit being capable of transmitting the sensor data to a display device and/or transmit the sensor data to a user device, such as a mobile, a computer, a tablet, and/or a laptop, where a user can access the sensor data. Sensors are especially advantageous when the air transport unit also comprises an electric component for transmission of data, and in particular when the air transport unit also comprises a ventilation hole facing the ambient environment, especially when the ventilation hole comprises a ventilation unit, and moreover it is advantageous when the air transport unit also comprises also comprises LEDs facing the ambient environment, e.g. LEDs emitting light in the PAR.

A controller may be provided for controlling the operation of one or more electric components. The controller may be configured for receiving a wireless signal. The controller may be configured for being controlled by direct current power line communication. The controller may be provided for controlling a single electric component or a group of electric components. The controller may allow a user of the air transport unit to control one or more operation parameters of an electric component and/or electrical group communicatively connected to the controller. The controller may be controlled at local control panel in the proximity of the air transport unit, and/or through a wireless connection by a mobile, a computer, a tablet, and/or a laptop.

A microphone may be provided for collecting audio data from the air transport unit. The microphone may be may be configured to transmit the audio data either wirelessly or through a wired connection to a processor unit. The processor unit being capable of transmitting the audio data to a user device, such as a mobile, a computer, a tablet, and/or a laptop, where a user can access the audio data.

A camera may be provided for collecting video data from the air transport unit. The camera may be may be configured to transmit the video data either wirelessly or through a wired connection to a processor unit. The processor unit being capable of transmitting the video data to a user device, such as a mobile, a computer, a tablet, and/or a laptop, where a user can access the video data. The camera may be provided to collect video data from inside the air duct. The camera may be provided on a surface opposite of the duct forming surface to collect video data from the surroundings of the air transport unit.

A radio transmitter may be provided for emitting a radio frequency signal from the air transport unit. The radio transmitter may be used for wireless communication.

A radio receiver may be provided for receiving a radio frequency signal transmitted to the air transport unit. The radio receiver may be used for wireless communication.

In an embodiment the composite board comprises a plurality of electric components, wherein the plurality of electric components are arranged in separate electrical groups that are separated by one or more continuous trenches in either the anode layer or the cathode layer, or in the anode layer and the cathode layer, and/or wherein at least one or more of the plurality of electric components comprises a controller capable of receiving and/or transmitting a data signal via the anode layer and/or the cathode layer using direct current power line communication.

Separating the electric components into groups may allow for separately providing power to the different electrical groups, thereby being able to selectively turn on/off the different electrical groups independently of each other. The trenches may be formed by milling of the cathode layer and/or the anode layer. The trenches may be formed by extrusion, e.g. if the anode layer and/or the cathode layer are formed by extrusion longitudinal trenches may be formed in the anode layer and/or cathode layer.

Direct current power line communication may be used for independently controlling the electric components within the plurality of electric components. In an embodiment where the air transport unit has an access point for wireless communication, a user may control the electric components within the plurality of components wirelessly from a tablet, a smart phone, a laptop, and/or a computer. In an embodiment where the air transport unit has a wireless/wired transmitter the air transport unit may transmit data from the plurality of electric components to a data storage, enabling a user to monitor the plurality of electric components wirelessly or through a wired connection.

A second aspect of the present invention relates to a vertical farming system comprising a support frame defining a bottom level and one or more standard levels arranged vertically above the bottom level, one or more air transport units, e.g. two or more air transport units, according to the first aspect of the invention arranged in the standard levels, wherein the carrier boards of the one, or two, or more air transport units are configured to house a growing organism. The vertical farming system may use any embodiment of the air transport system of the invention. The distances between the standard levels, and also the bottom level, may be chosen freely. For example, the distances between the standard levels may be chosen based on the plants, or other organisms, for which the vertical farming system is intended. In general, the distances between the standard levels may be in the range of 5 cm to 100 cm.

In the context of the invention a support frame is to be understood as any structure which is suitable for carrying at least one air transport unit. The support frame may be modular structure, wherein the bottom level is modular, and the one or more standard levels are modular, allowing a user of the vertical farming system to add and remove the bottom level and the one or more standard levels to the support frame as needed. The support frame may be a rack structure comprising one or more shelfs for receiving the one or more standard levels. In an embodiment the support frame comprises one or more fittings defining the one or more standard levels and/or the bottom level of the support frame. If the support frame has a rack structure, the one or more standard levels and/or the bottom level may be formed by the one or more fittings defining shelfs configured for receiving the one or more air transport units in the rack structure. Alternatively, the one or more air transport units may be provided with fittings for coupling the one or more air transport units to the one or more standard levels.

In the context of the invention the bottom level is to be understood as the lowest level in the vertical farming system. The bottom level may match the one or more standard levels and be configured for receiving an air transport unit.

In the context of the invention the one or more standard levels are to be understood as levels of the support frame configured to receive one or more air transport unit according to the first aspect of the invention.

Using a support frame for stacking the air transport unit vertically may allow for synergistic effects between the air transport units, e.g. the electric components of a first air transport unit may benefit a growing organism of a second air transport unit. In an embodiment where the first air transport unit is provided with LEDs, on a surface of the composite board opposite the duct forming surface, the LEDs may be configured to emit light onto a carrier board of a second air transport unit vertically underneath the composite board, e.g. for use as a growth/heat lamp for organic matter carried by the carrier board of the second air transport unit.

In an embodiment where a first air transport unit comprises a sprinkler system, said sprinkler system may be configured to spread fertiliser and/or water onto a carrier board of a second air transport unit vertically underneath the first air transport unit. The sprinkler system may be connected to a surface of the composite board of the first air transport unit opposite the duct forming surface. The support frame may for example comprise pipes or tubes with appropriate fluid connections to the sprinkler system(s) of the air transport unit(s). The fluid reservoir, e.g. the fluid reservoir of the air transport unit(s) may be part of the support frame or external to the support frame.

In an embodiment where a first air transport unit comprises a ventilation unit, said ventilation unit may be configured to facilitate an air flow around the carrier board of a second air transport unit vertically underneath the first air transport unit. The ventilation unit may be connected to a surface of the composite board of the first air transport unit opposite the duct forming surface.

In some embodiments where a first air transport unit comprises one or more sensors, the sensors may be configured for monitoring the conditions of organic matter carried by a carrier board of a second air transport unit vertically underneath the first air transport unit.

When writing a feature is comprised/connected or otherwise associated with the first air transport unit and/or the second air transport, the feature should not be construed as being limited to only the first air transport unit and/or the second air transport unit only, said feature may also be comprised/connected or otherwise associated with other air transport units within the vertical farming system. The mention of the first air transport and the second air transport unit is merely meant for exemplifying a manner in which the invention may be carried out. The vertical farming system may also comprise three, four, or more air transport unit stacked vertically and exhibiting some or all the above-mentioned synergistic effects.

In an embodiment a bottom board is arranged in the bottom level, which bottom board is configured to house a growing organism.

The bottom board may be a board substantially corresponding to a carrier board of the one or more air transport units. The bottom board may exhibit a synergistic effect with an air transport unit vertically above the bottom board. In an embodiment a first air transport unit vertically above the bottom board comprises a sprinkler system, said sprinkler system may be configured to spread fertiliser and/or water onto the bottom board vertically underneath the first air transport unit. The sprinkler system may be connected to a surface of the composite board of the first air transport unit opposite the duct forming surface.

In an embodiment where a first air transport unit comprises a ventilation unit, said ventilation unit may be configured to facilitate an air flow around the bottom board vertically underneath the first air transport unit. The ventilation unit may be connected to a surface of the composite board of the first air transport unit opposite the duct forming surface.

In some embodiments where a first air transport unit comprises one or more sensors, the sensors may be configured for monitoring the conditions of organic matter housed by the bottom board vertically underneath the first air transport unit.

The bottom board may have any shape as desired. The size of the bottom board may be selected freely. In some embodiments the bottom board may have a size and shape substantially corresponding to the carrier board and/or composite board of the one or more air transport unit. The thickness of the bottom board may reflect the purpose of the bottom board, and the requirements towards mechanical strength.

The bottom board may be extending in two dimensions so that it can be described as “planar”. The bottom board may also be defined in three dimensions and e.g. have a shape representing a section of a sphere, e.g. a hemispherical shape, or an arch.

The bottom board may be manufactured from a wide variety material. The bottom board may comprise or consist of wood, polymer, plastics, steel, plastic, alloy, glass, metal, etc.

The bottom board may in some embodiments comprise an anode layer and a cathode layer of an electrically conducting material, e.g. the bottom board may also be a composite board with appropriate electric components, e.g. sensors. Where the anode layer and the cathode layer are separated by an insulator of an electrically insulating material. The bottom board may also comprise an electric component in electrical connection with the anode layer and the cathode layer. The bottom board may be modified to substantially match a composite board of the one or more air transport unit.

In some embodiments the bottom level is configured for receiving an air transport unit according to the first aspect of the invention and the bottom board is the carrier board of the air transport.

In an embodiment the support frame comprises an anodic pillar electrically connected to the anode layer of at least one air transport unit and a cathodic pillar electrically connected to the cathode layer of the at least one air transport unit and a power supply capable of providing a constant voltage or a constant current between the anodic pillar and the cathodic pillar. Connecting the one or more of the air transport units to a power supply via the support frame assures that no excessive or complicated wiring is needed for supplying power to the one or more air transport units.

The anodic pillar and the cathodic pillar material may be chosen freely, from any electrically conducting materials suitable for conducting a current. However, it is preferred that the electrically conducting material comprises or is a metal. Preferred metals are metals selected from the list consisting of aluminium, magnesium, copper, titanium, steel, and their alloys. Metals may be anodised to provide the metal with an oxide layer on the surface, and in an embodiment the metal is anodised, e.g. by providing an oxide layer having a thickness of at least 10 μm. When the metal is anodised, the outer surface of the metal is electrically insulating so that an end user is protected from currents running through the electrically conducting materials, i.e. the anodic pillar and the cathodic pillar. Anodisation further protects the metal from being corroded. Anodised aluminium, magnesium, or titanium has a protective insulating layer which may prevent short circuiting and electrical shocks.

In some embodiments the anodic and pillar and the cathodic pillar may be used in conjunction with the anode layer and the cathode layer of the one or more air transport units to provide data communication with one or more electronic components of the one or more air transport units using direct current PLC. When data communication is desired the support frame may be fitted with appropriate data ports, e.g. standardised ports, such as those known as USB, HDMI, Display Port, etc. When data ports are included, appropriate electronic components will typically also be integrated in the support frame. When the vertical farming system comprises sensors, e.g. when the air transport unit and/or the bottom board comprises sensors, the sensors of individual air transport units, and when relevant the bottom board, the sensors may be used in the control of parameters, e.g. using appropriate electric components, between individual air transport units, and the anodic and the cathodic pillars may be used to transmit data, e.g. using PLC.

The anodic pillar and/or the cathodic pillar may be an integrated load bearing structure of the support frame. In an embodiment where the support frame has a rack structure at least one leg of the rack structure may be the anodic pillar and at least one other leg of the rack structure may be the cathodic pillar. In some embodiments the anodic pillar and the cathodic pillar are comprised in the same leg.

The anodic pillar and/or the cathodic pillar may be provided with one or more fittings configured for providing an electrical connection to the electrically conductive layers of the one or more air transport units. The one or more fittings may be an integrated component of the anodic pillar and/or the cathodic pillar or connected by other means to the anodic pillar and/or the cathodic pillar, e.g. by welding, gluing, or mechanical coupling.

In an embodiment the support frame comprises a coupling portion at the one or more standard levels and/or at the bottom level, and the one or more air transport units and/or the bottom board comprise a complementary coupling portion allowing releasable coupling of the bottom board and/or the air transport units with the frame. Thereby, a flexible vertical farming system is provided where individual air transport units may be removed from the vertical farming system when e.g. a crop is ready for harvesting, and another air transport unit with seedling plants may replace the removed air transport unit so that efficient handling of the plants is provided. It is especially advantageous when the air transport units have sensors or cameras allowing monitoring of the status of the plants so that they can be harvested at an optimal time. When the support frame comprises coupling portions and the air transport units and/or the bottom board comprise complementary coupling portions, it is preferred that the support frame comprises pipes and/or tubes fluidly connected to the sprinkler system of the air transport units, and that the coupling portions and the complementary coupling portions have appropriate fluid connection with valves so that removal of an air transport unit will close the valve and insertion of an air transport unit will open the valve.

In an embodiment the support frame comprises a coupling portion as one or more protrusions on which the one or more air transport units may rest on, in such an embodiment the one or more complementary coupling portions of the air transport units and/or the bottom board may simply be any surface suitable of resting stationary on the one or more protrusions of the support frame.

The support frame may be provided with a coupling portion in the form of an aperture or track, where the one or more air transport units and/or the bottom board comprises protrusion configured for engaging the aperture or track, thereby providing coupling the bottom board and/or the one or more air transport units to the support frame.

In an embodiment the coupling portion is a loop and the complementary coupling is hook, or vice versa. For example, the support frame may be provided with one or more metal loops fixedly connected to the support frame, and the bottom board and/or the air transport units may be provided with hooks configured to engage the loops.

The air transport unit is not limited to use in vertical farming systems. For example, the air transport unit can also be used in an indoor ventilation arrangement where sensors can monitor parameters, such as the air composition and temperature, and the parameters can be adjusted based on output from the sensors. An indoor ventilation arrangement can for example be used in a kitchen or any other room in a home.

It is noted that the invention relates to all possible combinations of features recited in the claims. Other objectives, features, and advantages of the present inventive concept will appear from the following detailed disclosure, from the attached claims as well as from the drawings. A feature described in relation to one of the aspects may also be incorporated in the other aspect, and the advantage of the feature is applicable to all aspects in which it is incorporated.

### BRIEF DESCRIPTION OF THE DRAWINGS

In the following the invention will be explained in greater detail with the aid of an example and with reference to the schematic drawings, in which

FIG. 1 depicts a schematic cross-sectional view of an embodiment of an air transport unit according to the present invention;

FIG. 2 depicts a schematic view of an opposing surface of a composite board in an embodiment of the invention;

FIG. 3 depicts a schematic view of a duct forming surface of a composite board in an embodiment of the invention;

FIG. 4 depicts a cross-sectional view of an embodiment of an air transport unit in an embodiment according to the invention;

FIG. 5 depicts a perspective view of an embodiment of an air transport unit according to the present invention.

FIG. 6 depicts a cross-sectional perspective close-up view of an electric component mounted in a composite board of an air transport unit according to an embodiment of the present invention.

FIG. 7 depicts a perspective view of an embodiment of a vertical farming system according to the present invention.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

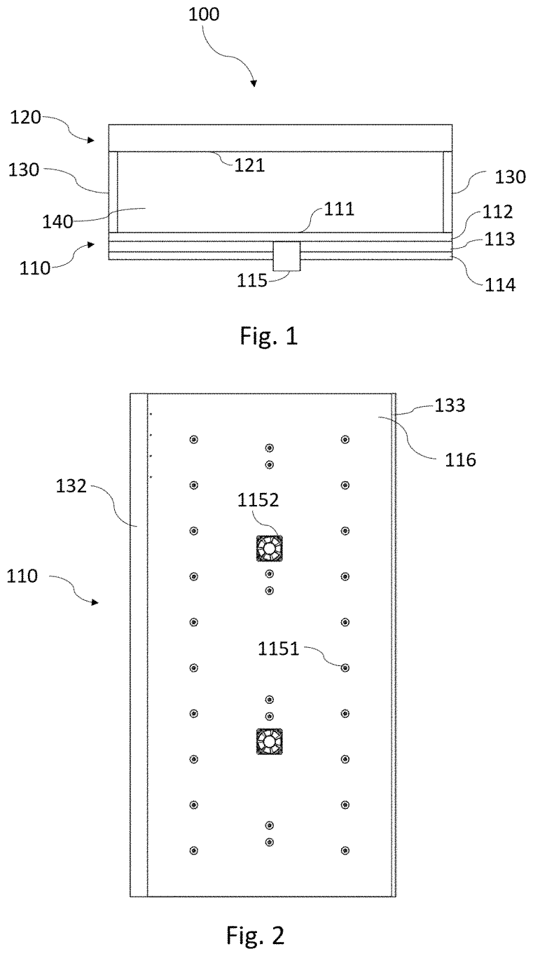

Referring initially to FIG. 1, which depicts a schematic cross-sectional view of an embodiment of an air transport unit 100 according to the present invention. The air transport unit 100 in the presented embodiment comprises a carrier board 120, two side walls 130, and a composite board 140. The carrier board 120 has a generally planar geometry. The carrier board 120 comprises a duct forming surface 121, which defines a part of an air duct 140. Connected to the carrier board are two side walls 130. The side walls 130 also defining a part of the air duct 140. The side walls 130 may in some embodiments be integrated components of either the composite board 110 and/or the carrier board 120. The side walls 130 may be connected to either the carrier board 120 and/or the composite board 110 by welding, adhesion, or mechanical coupling. In connection with the side walls 130 is the composite board 110. The composite board 110 comprises an anode layer 112, an insulator layer 113, a cathode layer 114, and an electric component 115. In the shown embodiment the anode layer 112 comprises a duct forming surface 111, though in other embodiments it may be the cathode layer 114 comprising the duct forming surface 111. The duct forming surface 111 of the anode layer 112 forming part of the air duct 140. In electrical connection with the cathode layer 114 and the anode layer 112 is an electric component 115. The electric component 115 is in the shown embodiment connected to the composite board 110 by being introduced through an opposing surface 116 of the composite board. The opposing surface 116 being a surface opposite to the duct forming surface 111. Connecting the electric component 115 in such a manner may be advantageous if the air transport unit is to be used as a light fixture and the electric component 115 is an LED configured for emitting light, since such a connection allows the electric component 115 to emit light away from the air transport unit 100. In the shown embodiment the side walls 130, the composite board 110, and the carrier board 120 all have a general planar geometry resulting in a rectangular air duct 140. The invention is not limited to an air duct 140 with a rectangular cross-section, in some embodiments no side walls 130 are present and instead the carrier board 120 and the composite board 110 are connected directly together, e.g. the composite board 110 and the carrier board 120 may curve and connect at each curving end to form an air duct with a biconvex cross-section, other air duct geometries are also within the scope of the invention. When no sidewalls 130 are present, the carrier board 120 and the composite board 110 may be connected directly to each other, they may be connected by adhesion, welding, or mechanical coupling.

Referring to FIG. 2, which depicts a schematic view of an opposing surface 116 of a composite board 120 in an embodiment of the invention. Mounted in the opposing side 116 of the composite board 120 are several electric components 1151, 1152. The opposing surface 116 being opposite a duct forming surface of the composite board 120. The electric components 1151, and 1152 may be the same type of electric component or may indicate different types of electric components, e.g. camera, sensors, LEDs, ventilation units, cooling unit, and/or heating units. In the shown embodiment the first electric components 1151 are a plurality of LEDs configured to emit light away from the air transport unit 100, and the second electric components 1152 are two ventilation units configured to provide a supply/exhaust air flow to and away from the air duct. Placed on opposing side surfaces sides of the composite board 110 are a first fitting 132 and a second fitting 133. The fittings 131, 132 may be used for protecting the side surfaces of the composite board 110, and to minimize risk of delamination of layers.

The electric components 1151, and 1152, may be separated into groups independent or dependent on type of electric component. The first electric components 1151 may be separated into a first electrical group. The second electric components 1152 may be separated into a second electrical group. In some embodiments electrical groups comprising more than one type of electric components may be formed, e.g. the first electric components 1151 being in an electrical group with the second electric components 1152. In an embodiment where the composite board 120 comprises one or more ventilation units, said one or more ventilation units may be mounted in one or more ventilation holes of the composite board 120. A ventilation hole may be a through-going hole through the composite board 120, connecting the air duct to an exterior. Thereby, facilitating air transport between the air duct and an exterior.

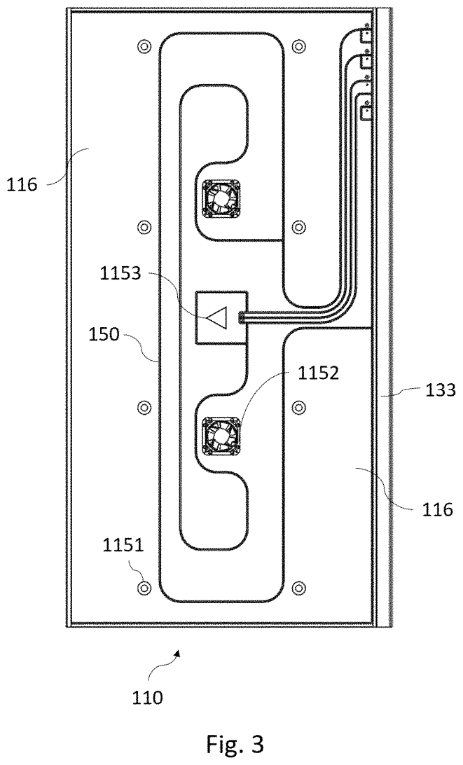

Referring to FIG. 3, which depicts a schematic view of a duct forming surface 116 of a composite board 120 in an embodiment of the invention. The composite board 120 have been provided with several electric components 1151, 1152, and 1153, which are either mounted on the duct forming surface 116 or in a surface opposite the duct forming surface 116. The electric components 1151, 1152, and 1153 may be the same type of electric component or may indicate different types of electric components, e.g. cameras, sensors, LEDs, ventilation units, cooling unit, and/or heating units. In the shown embodiment the first electric components 1151 are a plurality of LEDs configured to emit light, the second electric components 1152 are two ventilation units configured to provide a supply/exhaust air flow to and away from the air duct, and the third electric component 1153 is a sensor configured to collect sensor data, e.g. temperature, CO₂ level, moisture level, and etc.

In the shown embodiment the first electric components 1151, the second electric components 1152, and the third electric component 1153 have been separated into three electrical groups. The separation of the electric components 1151, 1152 and 1153 have been carried out by a plurality of trenches 150. The separation of electric components 1151, 1152, and 1153 into electrical groups may be carried out by one or more trenches 150. The trenches 150 may be formed by milling through either the anode or the cathode layer of the composite board. The trenches may be formed during formation of the anode or the cathode layer, e.g. if the electrically conductive layers are formed by extrusion trenches may be formed by extrusion. The trenches 150 may also allow for separate PLC control of the electrical groups formed by the trenches 150.

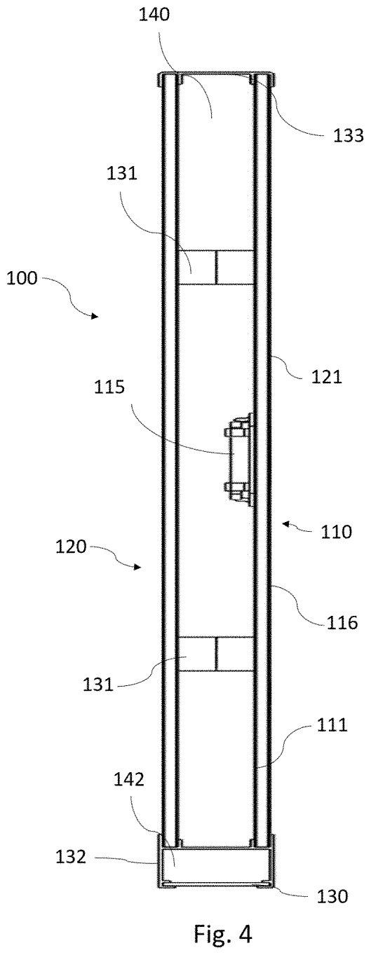

Referring to FIG. 4, which depicts a cross-sectional view of an embodiment of an air transport unit 100 in an embodiment according to the invention. The carrier board 120 and the composite board 110 are separated by an air duct 140. A plurality of support structures 131 have been placed in the air duct 140. The support structures are connected to the duct forming surface 121 of the carrier board 120 at one end and to the duct forming surface 111 of the composite board 110 at another end. In some embodiments only one support structure is placed in the air duct. The support structures 131 may be used for adding structural integrity to the air transport unit 100, e.g. to avoid either the carrier board 120 or the composite board 110 curving due to gravity and/or forces affecting surfaces of the composite board 120 and/or the carrier board. For example, if the air transport unit 100 is used in a farming system and the carrier board 120 is to support a growing organism, the support structures 131 may assure the carrier board 120 does not bend due to the weight of the growing organism. In another example, where the air transport unit 100 is used as a lighting fixture and hung from a ceiling or similar, the support structures 130 may connect the carrier board 120 and the composite board 110 to assure they do not curve due to gravity. In some embodiments the air transport unit 100 comprises one or more support structures 131 arranged in the air duct and connected to the carrier board 110 and the composite board 120. The support structures 130 may be constructed from any material, preferably the structures are constructed from a high strength polymer. The support structures 130 may be formed as pillars, cubes, pyramids, cones, etc.

A first fitting 132 and a second fitting 133 are provided in connection with both the carrier board 120 and the composite board 110. The fittings 132, and 133 are used for connecting the carrier board 120 and the composite board 110. The fittings 132, and 133 are connected to the carrier board 120 and the composite board 110 on opposing side surfaces of the composite board 110 and the carrier board 120. In the shown embodiment the fittings 132, and 133 delimits the air duct 140 together with duct forming surfaces 111, and 121 of the carrier board 120 and the composite board 110. The first fitting 132 and the second fitting 133 are provided with protrusions forming a first U-shaped receiving portion and a second U-shaped receiving portion on each fitting. The first U-shaped receiving portion is configured for snugly receiving the composite board 110, and the second U-shaped receiving portion is configured for snugly receiving the carrier board 120. The first fitting 132 further forms, in conjunction with a side wall 130, an additional duct 142. The additional duct 142 may be used as a housing section for housing one or more electric components or non-electric components. The fittings 132, and 133 may be manufactured at least partly from a conductive material allowing the fittings to conduct a current to the anode layer and/or the cathode layer of the composite board 110. In some embodiments the fittings 132, 133 may be provided with coupling portions for mechanically coupling the air transport unit 100 with another structure. The coupling portions may be in the form of hooks, bars, and/or other male connector parts. Alternatively, the coupling portions may be in the form openings, flanges, or other female connector parts. Preferably, the coupling portions provides a mechanical connection and/or an electrical connection.

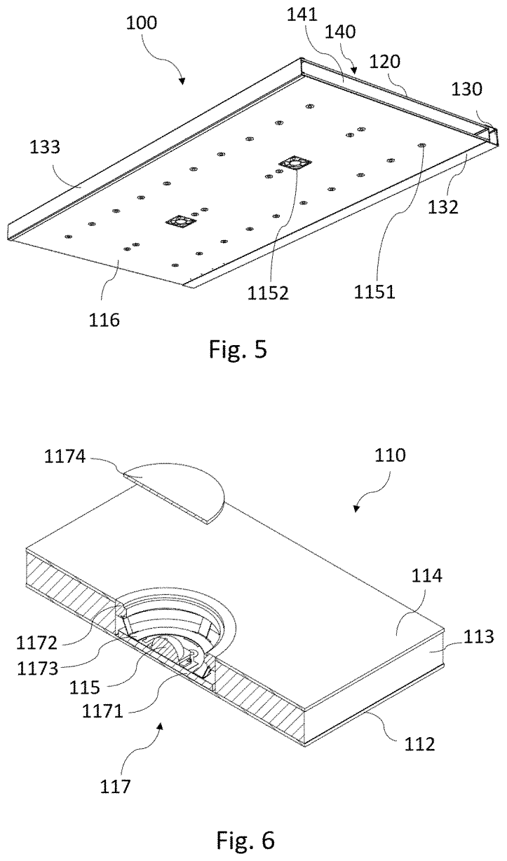

Referring to FIG. 5, which depicts a perspective view of an embodiment of an air transport unit 100 according to the present invention. The composite board 110 comprises a plurality of first electric component 1151 and a plurality of second electric component 1152. The first electric components 1151 are a plurality of LEDs and the second electric components 1152 are a plurality of ventilation units. The first electric components 1151 are mounted in an opposing side 116 of the composite board 110. The second electrical units 1152 are mounted in ventilation holes of the composite board 110. Mounted on side surfaces of the composite board 110 and a carrier board 120 are a first fitting 132 and a second fitting 133. The composite board 110 and the carrier board 120 are connected to form an air inlet 141 facilitating an air flow between an ambient environment and an air duct 140. The air inlet 141 is formed at a first longitudinal end of the composite board 110 and the carrier board 120. At a second longitudinal end opposite the first longitudinal end, the carrier board 120 and the composite board 110 are connected to form an air outlet, not shown on FIG. 5. The air outlet facilitates an air flow between an ambient environment and the air duct 140. The air inlet 141 and the air outlet allows for a longitudinal air flow through the air duct 140. The air inlet 141 and the air outlet are formed in-between duct forming surfaces of the composite board 110 and the carrier board 120.

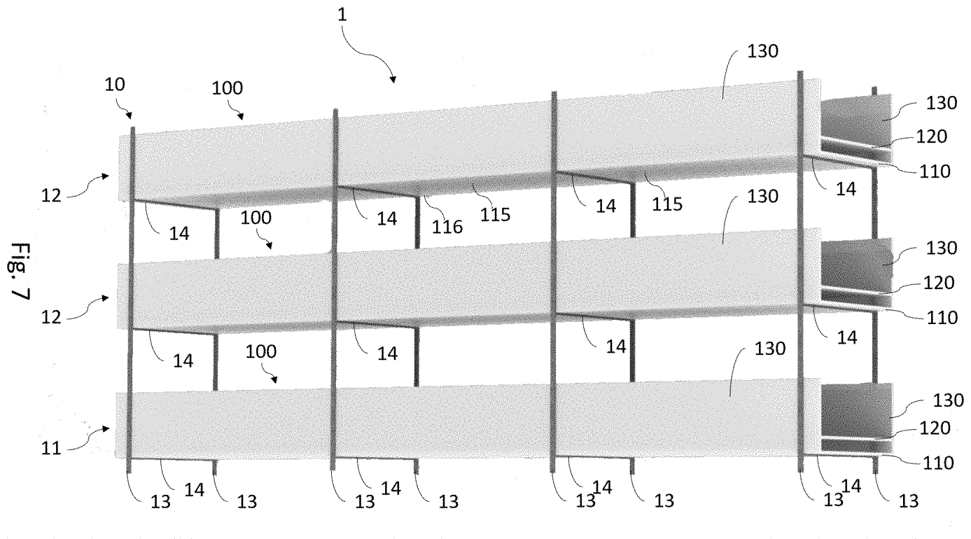

Referring to FIG. 6, which depicts a perspective close-up view of an electric component 115 mounted in a composite board 110 of an air transport unit 100 according to an embodiment of the present invention. The electric component 115 is electrically connected to the composite board 110 via an adapter 117. The adapter 117 comprises a circuit board 1171 in direct electrical connection with a cathode layer 112 of the composite board 110. The circuit board 110 may be attached to the cathode layer 114 in any way, e.g. by soldering, gluing or the like. In electrical connection with the circuit board 1171 is a resilient member 1173. The resilient member 1173 may be in electrical connected with an anode layer 114 of the composite board 110 directly or in-directly. In the shown embodiment the resilient member 1173 is in-directly in electrical connection with the anode layer 114 via a retaining member 1172. The resilient member 1173 is sandwiched in-between the circuit board 1171 and the retaining member 1172. In the shown embodiment the resilient member 1173 comprises several resilient legs providing an electrical connection to the retaining member 1172. The retaining member 1172 is in direct electrical connection with the anode layer 114. In other embodiments the circuit board 1171 is in direct electrical connection with the anode layer 114, and the resilient member 1173 or the retaining member 1172 are in direct electrical connection with the cathode layer 112. The retaining member 1172 may be introduced into a conductive layer of the composite board 110 by screwing, soldering, mechanical coupling, or adhesion. In some embodiments where the electric component 115 is a LED, or other fragile electric components, it may be advantageous to provide the adapter 117 with a cover 1174. The cover being connected to either the resilient member 1173 or the retaining member 1172 to cover and protect the electric component 115. The cover is 1173 is preferable an optical transparent cover, when the electric component 115 is a LED.

Referring to FIG. 7, which depicts a perspective view of an embodiment of a vertical farming system 1 according to the present invention. The vertical farming system 1 comprises a support frame 10. In the shown embodiment the support frame 10 is formed as a rack structure, though the support structure 10 is not limited to a rack structure. The support structure 10 comprises a bottom level 11 and two standard levels 12. The support structure 10 may also comprise one standard level 12, three standard levels 12, or more. In the shown embodiment the bottom level 11 and the standard levels 12 match each other, though in some embodiments the bottom level 11 and the one or more standard levels 12 may differ from each other. In the shown embodiment, the support structure 10 comprises a plurality of vertically extending legs 13, preferably the legs 13 are provided in pairs. The pairs of legs 13 may be connected by a transversal connector 14. The transversal connector 14 may be a rod or a beam. The transversal connector 14 may define the bottom level 11 and/or the one or more standard levels 12. The transversal connector 14 may form shelfs for receiving the one or more air transport units 100. In other embodiment the vertically extending legs 13 are not connected with the transversal connector 14, instead fittings for receiving the one or more air transport units 100 are integrated or connected to the vertically extending legs. The transversal connector 14 may also be used in conjunction with fittings for receiving one or more air transport units 100 on the support frame 10. Fittings may define the bottom level 11 and/or the one or more standard levels 12. In some embodiments the fittings may be used in conjunction with the transversal connector 14 either to define in cooperation the bottom level 11 and/or the one or more standard levels 12. The air transport 100 units may be provided with fittings comprising coupling portion configured for coupling the air transport units 100 to the support frame 10. In some embodiments the support frame is provided with fittings comprising coupling portion configured for coupling the air transport units 100 to the support frame 10. The coupling between the support frame 10 and air transport units 100 may be a releasable coupling or a permanent coupling.

The vertically extending legs 13 may be used as means for conducting power to the one or more air transport units 100. In an embodiment where the vertically extending legs 13 are delivered in pairs of a first vertically extending leg 13 and a second vertically extending leg 13, the first vertically extending leg 13 may function as an anodic pillar electrically connected to the anode layer of at least one air transport unit 100, and the second vertically extending leg 13 may function as a cathodic pillar electrically connected to the cathode layer of the at least one air transport unit 100. The system may further comprise a power supply capable of providing a constant voltage or a constant current between the anodic pillar and the cathodic pillar.

In the shown embodiment three air transport units 100 are comprised in the vertical farming system 1. The invention is not limited to three air transport units 100, the vertical farming system 1 may comprise one, two, four or more air transport units 100. The air transport units 100 in the standard levels of the shown embodiment are arranged with the opposing surfaces 116 of the composite boards 120 oriented in a downward facing direction. Mounted in the opposing surface 116 of the one or more air transport units 100 are a plurality of electric components 115. The plurality of electric components 115 is LEDs in the shown embodiment. The LEDs are mounted in the opposing side 116 to allow the LEDs to shine down on a carrier board 120 of an air transport unit located 100 below the LEDs. Each air transport units 100 are provided with side walls 130. The sidewalls 130 extends vertically above the carrier board 120 of the respective air transport unit 100. The side walls 130 extends to form a channel open at the top and at each longitudinal end of the air transport unit 100. The channel may be used as an enclosure for housing organic matter.

The air transport units 100 extends longitudinally. In the shown embodiment, the air ducts of the air transport unit 100 extends longitudinally and have openings at each longitudinally end for facilitating a longitudinal air flow through the air duct.

What is claimed is:

1-12. (canceled)

13. An air transport unit comprising a composite board comprising an anode layer and a cathode layer of an electrically conducting material, which anode layer and cathode layer are separated by an insulator of an electrically insulating material, the composite board further comprising an electric component in electrical connection with the anode layer and the cathode layer, the air transport unit further comprising a carrier board, wherein the composite board and the carrier board each have a duct forming surface, which carrier board and composite board are arranged so that an air duct forms between the duct forming surfaces.

14. The air transport unit according to claim 13, wherein the carrier board comprises a surface configured to house a growing organism.

15. The air transport unit according to claim 13, wherein the composite board comprises a ventilation hole extending through the anode layer, the insulator and the cathode layer, which ventilation hole is configured to facilitate an air flow between the air duct and ambient environment of the air transport unit.

16. The air transport unit according to claim 15, wherein the ventilation hole comprises a ventilation unit in electrical connection with the anode layer and the cathode layer.

17. The air transport unit according to claim 13, wherein the electric component is one or more LEDs, the anodes of which are in electrical connection with the anode layer and the cathodes of which are in electrical connection with the cathode layer, wherein the one or more LEDs are configured to emit light at a wavelength within the photosynthetically active radiation (PAR) and/or ultraviolet light and/or infrared light away from the surface of the composite board opposite the air duct.

18. The air transport unit according to claim 13, wherein the electric component is a liquid pump and the air transport unit further comprises a sprinkler system comprising a pipe in fluid communication with a liquid reservoir and the liquid pump, the pipe having a sprinkler configured to distribute a liquid from the surface of the composite board opposite the air duct.

19. The air transport unit according to claim 13, wherein the electric component is selected from the list consisting of a heating unit, a cooling unit, a sensor, a controller, a microphone, a camera, a radio transmitter, a radio receiver, an antenna and an access point for wireless communication.

20. The air transport unit according to claim 13, wherein the composite board comprises a plurality of electric components,
wherein the plurality of electric components is arranged in separate electrical groups that are separated by one or more continuous trenches in either the anode layer or the cathode layer, or in the anode layer and the cathode layer, and/or
wherein at least one or more of the plurality of electric components comprises a controller capable of receiving and/or transmitting a data signal via the anode layer and/or the cathode layer using direct current power line communication.

21. A vertical farming system comprising:
a support frame defining a bottom level and one or more standard levels arranged vertically above the bottom level,
one or more air transport units comprising a composite board comprising an anode layer and a cathode layer of an electrically conducting material, which anode layer and cathode layer are separated by an insulator of an electrically insulating material, the composite board further comprising an electric component in electrical connection with the anode layer and the cathode layer, the air transport unit further comprising a carrier board, wherein the composite board and the carrier board each have a duct forming surface, which carrier board and composite board are arranged so that an air duct forms between the duct forming surfaces arranged in the standard levels,
wherein the carrier boards of the one or more air transport units are configured to house a growing organism.

22. The system according to claim 21, wherein a bottom board is arranged in the bottom level, which bottom board is configured to house a growing organism.

23. The system according to claim 21, wherein the support frame comprises an anodic pillar electrically connected to the anode layer of at least one air transport unit and a cathodic pillar electrically connected to the cathode layer of the at least one air transport unit and a power supply capable of providing a constant voltage or a constant current between the anodic pillar and the cathodic pillar.

24. The system according to claim 21, wherein the support frame comprises a coupling portion at the one or more standard levels and/or at the bottom level, and the one or more air transport units and/or the bottom board comprise a complementary coupling portion allowing releasable coupling of the bottom board and/or the air transport units with the frame.

25. The system according to claim 21, wherein the composite board comprises a ventilation hole extending through the anode layer, the insulator and the cathode layer, which ventilation hole is configured to facilitate an air flow between the air duct and ambient environment of the air transport unit.

26. The system according to claim 25, wherein the ventilation hole comprises a ventilation unit in electrical connection with the anode layer and the cathode layer.

27. The system according to claim 21, wherein the electric component is one or more LEDs, the anodes of which are in electrical connection with the anode layer and the cathodes of which are in electrical connection with the cathode layer, wherein the one or more LEDs are configured to emit light at a wavelength within the photosynthetically active radiation (PAR) and/or ultraviolet light and/or infrared light away from the surface of the composite board opposite the air duct.

28. The system according to claim 21, wherein the electric component is a liquid pump and the air transport unit further comprises a sprinkler system comprising a pipe in fluid communication with a liquid reservoir and the liquid pump, the pipe having a sprinkler configured to distribute a liquid from the surface of the composite board opposite the air duct.

29. The system according to claim 21, wherein the electric component is selected from the list consisting of a heating unit, a cooling unit, a sensor, a controller, a microphone, a camera, a radio transmitter, a radio receiver, an antenna and an access point for wireless communication.

30. The system according to claim 21, wherein the composite board comprises a plurality of electric components,
wherein the plurality of electric components is arranged in separate electrical groups that are separated by one or more continuous trenches in either the anode layer or the cathode layer, or in the anode layer and the cathode layer, and/or
wherein at least one or more of the plurality of electric components comprises a controller capable of receiving and/or transmitting a data signal via the anode layer and/or the cathode layer using direct current power line communication.
